(19) United States
(12) Patent Application Publication
(10) Pub. No.: US 2022/0149762 A1
(43) Pub. Date: May 12, 2022

(54) MOTOR CONTROLLER

(71) Applicant: Global Mixed-mode Technology Inc., Hsin-Chu (TW)

(72) Inventor: Chien-Lun Chu, Hsinchu County (TW)

(21) Appl. No.: 17/095,682

(22) Filed: Nov. 11, 2020

(51) Int. Cl. H02P 6/18; H02P 27/08; H02P 29/024; H02P 6/08; G01R 33/07; G01D 5/20

(52) U.S. Cl. CPC H02P 6/18; H02P 27/08; G01D 5/208; H02P 6/08; G01R 33/072; H02P 29/0241

(57) ABSTRACT

A motor controller is configured to obtain a plurality of physical parameters. The motor controller comprises a selecting circuit, a Hall signal processing unit, a temperature sensor, a transistor, a control unit, and a driving circuit. The Hall signal processing unit is configured to generate a Hall signal. The temperature sensor is configured to generate a temperature signal. The control unit comprises a judging unit and the judging unit is configured to determine whether the motor controller is operated in a normal operation mode or a test mode. The judging unit is used for informing the selecting circuit to output the temperature signal or the Hall signal based on a first test enabling signal or a second test enabling signal.

### BACKGROUND OF THE INVENTION

### 1. Field of the Invention

The present invention relates to a motor controller, and more particularly, to a motor controller which is capable of obtaining a plurality of physical parameters in a test mode.

### 2. Description of the Prior Art

Currently some motor controllers comprise a plurality of sensing elements (e.g., Hall sensor, temperature sensor) for the internal control signals to use. However, the user cannot obtain the physical parameters outputted by the plurality of sensing elements by an external measurement. Conventionally, a pulse width modulation pin can be used to receive a test enabling signal and enter a test mode. Also, the pulse width modulation pin can be used to output a Hall signal. Since the number of pins is related to the package cost, the number of pins should be reduced to save the cost and make the product more competitive. Thus, it has become an important issue to make good use of currently available pins, such that the physical parameters can be obtained by entering the test mode.

Thus, what is needed is the motor controller which is capable of obtaining the physical parameters.

### SUMMARY OF THE INVENTION

According to the present invention, a motor controller which is capable of obtaining a plurality of physical parameters in a test mode is provided. The motor controller is configured to drive a motor. The motor controller comprises a command pin, a speed signal pin, a selecting circuit, a Hall signal processing unit, a temperature sensor, a transistor, a control unit, and a driving circuit. The selecting circuit is coupled to the speed signal pin. The driving circuit is used for supplying a motor current to the motor. The Hall signal processing unit is configured to generate a Hall signal while the temperature sensor is configured to generate a temperature signal. The control unit comprises a judging unit and the judging unit is configured to determine whether the motor controller is operated in a normal operation mode or a test mode. The judging unit is coupled to the command pin. The judging unit is used for informing the selecting circuit to output a temperature signal via the speed signal pin based on a first test enabling signal. The judging unit is used for informing the selecting circuit to output a Hall signal via the speed signal pin based on a second test enabling signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above-mentioned and other objects, features, and advantages of the present invention will become apparent with reference to the following descriptions and accompanying drawings, wherein:

FIG. 1 is a pin assignment showing a motor controller according to one embodiment of the present invention; and

FIG. 2 is a circuit diagram showing the motor controller according to one embodiment of the present invention.

### DETAILED DESCRIPTION

Preferred embodiments according to the present invention will be described in detail with reference to the drawings.

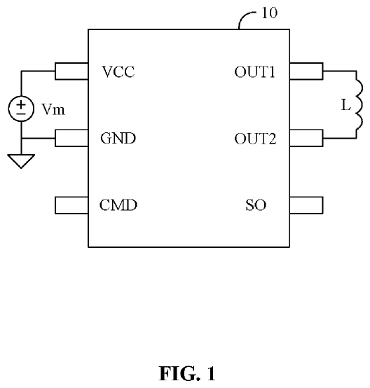

FIG. 1 is a pin assignment showing a motor controller 10 according to one embodiment of the present invention. The motor controller 10 is used for driving a motor, where the motor has a motor coil L. The motor controller 10 comprises a voltage supply pin VCC, a ground pin GND, a command pin CMD, a first output pin OUT1, a second output pin OUT2, and a speed signal pin SO. The voltage supply pin VCC and the ground pin GND are coupled to a voltage source Vm for supplying the voltage to the motor controller 10. The command pin CMD is configured to receive a pulse width modulation signal for adjusting the motor speed. The speed signal pin SO is configured to output a speed signal. The first output pin OUT1 and the second output pin OUT2 are coupled to the motor coil L for driving the motor.

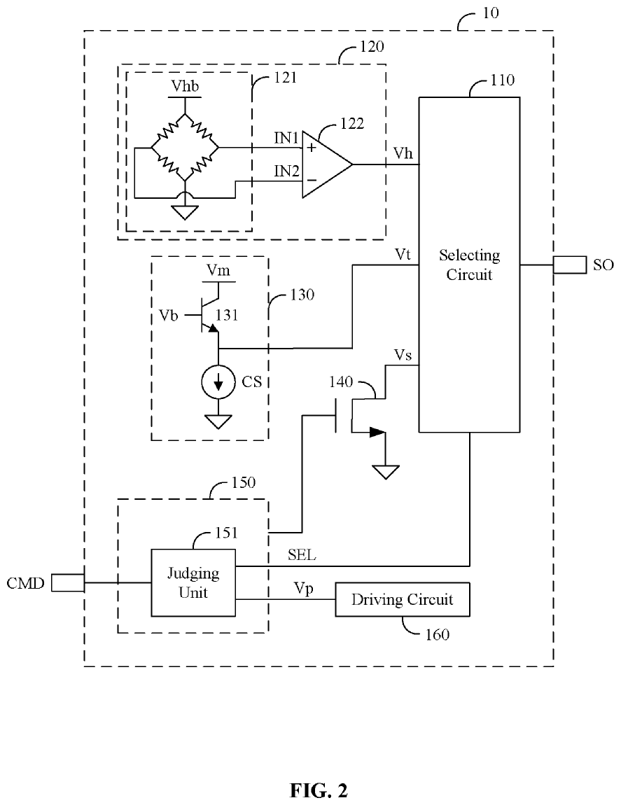

FIG. 2 is a circuit diagram showing the motor controller 10 according to one embodiment of the present invention. The motor controller 10 further comprises a selecting circuit 110, a Hall signal processing unit 120, a temperature sensor 130, a transistor 140, a control unit 150, and a driving circuit 160. The Hall signal processing unit 120 comprises a Hall sensor 121 and an amplifier 122, where the Hall sensor 121 is placed near the motor for sensing the variation of the magnetic field. The Hall sensor 121 is coupled to a voltage source Vhb for generating a first output signal and a second output signal. The amplifier 122 comprises a first input terminal IN1 and a second input terminal IN2. The first input terminal IN1 is coupled to the first output signal and the second input terminal IN2 is coupled to the second output signal, so as to generate a Hall signal Vh to the selecting circuit 110. Furthermore, the Hall signal Vh is related to a physical parameter (e.g., magnetic field).

The temperature sensor 130 comprises a bipolar transistor 131 and a current source CS. The bipolar transistor 131 has an emitter, a base, and a collector. The collector of the bipolar transistor 131 is coupled to the voltage source Vm. The base of the bipolar transistor 131 is coupled to a reference voltage Vb, where the reference voltage Vb has a zero temperature coefficient. The emitter of the bipolar transistor 131 is coupled to the current source CS for generating a temperature signal Vt to the selecting circuit 110, where the temperature signal Vt varies with the temperature by a factor of 25 mV/° C. As shown in FIG. 2, the bipolar transistor 131 may be an NPN bipolar transistor. Furthermore, the temperature signal Vt is related to a physical parameter (e.g., temperature).

The control unit 150 is coupled to the transistor 140 for generating a speed signal Vs to the selecting circuit 110. The control unit 150 comprises a judging unit 151. The judging unit 151 is configured to determine whether the motor controller 10 is operated in a normal operation mode or a test mode. The judging unit 151 is coupled to the command pin CMD, so as to generate an N-bit digital signal SEL to the selecting circuit 110 and a pulse width modulation signal Vp to the driving circuit 160, where N is equal to 2. The driving circuit 160 is used for supplying a motor current to the motor, where the driving circuit 160 may have an H-bridge circuit.

When the command pin CMD receives a normal pulse width modulation signal, the judging unit 151 may set the digital signal SEL to 00, so as to inform the selecting circuit 110 to couple the speed signal Vs with the speed signal pin SO. At this moment the motor controller 10 is operated in the normal operation mode. The judging unit 151 is configured to couple the pulse width modulation signal Vp with the command pin CMD for controlling the motor to rotate. When the command pin CMD receives a first test enabling signal, the judging unit 151 may set the digital signal SEL to 01, so as to inform the selecting circuit 110 to couple the temperature signal Vt with the speed signal pin SO. At this moment the motor controller 10 is operated in the test mode. When the command pin CMD receives a second test enabling signal, the judging unit 151 may set the digital signal SEL to 10, so as to inform the selecting circuit 110 to couple the Hall signal Vh with the speed signal pin SO. At this moment the motor controller 10 is also operated in the test mode.

More specifically, there are many ways of generating the first test enabling signal and the second test enabling signal to enter the test mode. According to one embodiment of the present invention, the first test enabling signal may be a high-frequency signal with a first frequency and the second test enabling signal may be a high-frequency signal with a second frequency. The first frequency is greater than a first pre-determined frequency and the first frequency is less than a second pre-determined frequency. The second frequency is greater than a third pre-determined frequency and the second frequency is less than a fourth pre-determined frequency. The first pre-determined frequency is less than the second pre-determined frequency. The third pre-determined frequency is less than the fourth pre-determined frequency. The second pre-determined frequency is less than the third pre-determined frequency.

According to one embodiment of the present invention, the motor controller 10 can be applied to a single-phase or polyphase configuration. The motor controller 10 is configured to drive a motor. The motor controller comprises the command pin CMD, the speed signal pin SO, the selecting circuit 110, the Hall signal processing unit 120, the temperature sensor 130, the transistor 140, the control unit 150, and the driving circuit 160. The driving circuit is used for supplying a motor current to the motor. The control unit 150 comprises the judging unit 151 and the judging unit 151 is configured to determine whether the motor controller is operated in the normal operation mode or the test mode. The judging unit is coupled to the command pin. The judging unit is configured to obtain a plurality of physical parameters based on the first test enabling signal and the second test enabling signal. The selecting circuit 110 is coupled to the speed signal pin SO, where the selecting circuit 110 is used for outputting the Hall signal Vh and the temperature signal Vt. The Hall signal Vh and the temperature signal Vt are related to a plurality of physical parameters. The present invention has the advantage that a plurality of physical parameters can be obtained in the test mode without additional pins.

While the present invention has been described by the preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A motor controller configured to drive a motor, the motor controller comprising:
a first pin;
a second pin;
a selecting circuit, coupled to the second pin;
a driving circuit, configured to supply a driving current to the motor; and
a control unit, comprising a judging unit, wherein the judging unit is configured to determine whether the motor controller is operated in a normal operation mode or a test mode, the judging unit is coupled to the first pin, and the judging unit is used for informing the selecting circuit to output a temperature signal via the second pin based on a first test enabling pin.

2. The motor controller of claim 1, wherein the first test enabling pin has a first frequency, the first frequency is greater than a first pre-determined frequency, the first frequency is less than a second pre-determined frequency, and the first pre-determined frequency is less than a second pre-determined frequency.

3. The motor controller of claim 1, wherein the first pin is a command pin and the second pin is a speed signal pin.

4. The motor controller of claim 1, wherein the motor controller further comprises a temperature sensor, and the temperature sensor is configured to generate the temperature signal.

5. The motor controller of claim 4, wherein the temperature sensor comprises:
a bipolar transistor, coupled to a first voltage source; and
a current source, coupled to the bipolar transistor for generating the temperature signal to the selecting circuit.

6. The motor controller of claim 1, wherein the judging unit is used for informing the selecting circuit to output a Hall signal via the second pin based on a second test enabling pin.

7. The motor controller of claim 6, wherein the second test enabling pin has a second frequency, the second frequency is greater than a third pre-determined frequency, the second frequency is less than a fourth pre-determined frequency, and the third pre-determined frequency is less than a fourth pre-determined frequency.

8. The motor controller of claim 6, wherein the motor controller further comprises a Hall signal processing unit, and the Hall signal processing unit is configured to generate the Hall signal.

9. The motor controller of claim 8, wherein the Hall signal processing unit comprises:
a Hall sensor, coupled to a second voltage source for generating a first output signal and a second output signal; and
an amplifier, comprising a first input terminal and a second input terminal, wherein the first input terminal is coupled to the first output signal and the second input terminal is coupled to the second output signal, so as to generate the Hall signal to the selecting circuit.

10. A motor controller configured to drive a motor, the motor controller comprising:
a first pin;
a driving circuit, configured to supply a driving current to the motor; and
a control unit, comprising a judging unit, wherein the judging unit is configured to determine whether the motor controller is operated in a normal operation mode or a test mode, the judging unit is coupled to the first pin, and the judging unit is used for obtaining a plurality of physical parameters based on a first test enabling signal and a second test enabling signal.

11. The motor controller of claim 10, wherein the motor controller further comprises:
a second pin; and
a selecting circuit, coupled to the second pin, wherein the selecting circuit is used for outputting a Hall signal and a temperature signal, and the Hall signal and the temperature signal are related to the plurality of physical parameters.

12. The motor controller of claim 11, wherein the first pin is a command pin and the second pin is a speed signal pin.
